(19) United States
(12) Patent Application Publication
(10) Pub. No.: US 2024/0412887 A1
(43) Pub. Date: Dec. 12, 2024

(54) FLEX ION TRAP INTERCONNECT

(71) Applicant: Quantinuum LLC, Broomfield, CO (US)

(72) Inventors: Robert Horning, Broomfield, CO (US); Todd Klein, Saint Paul, MN (US)

(21) Appl. No.: 18/391,967

(22) Filed: Dec. 21, 2023

Related U.S. Application Data
(60) Provisional application No. 63/443,249, filed on Feb. 3, 2023.

(51) Int. Cl. G21K 1/00; B82Y 10/00; G06N 10/20; G06N 10/40; G21K 1/087

(52) U.S. Cl. CPC G21K 1/003; B82Y 10/00; G06N 10/20; G06N 10/40; G21K 1/087

(57) ABSTRACT

A flex ion trap interconnect for a quantum computing system is provided. The flex ion trap interconnect may be configured for operation in the temperature and pressure required by a vacuum chamber. The flex ion trap interconnect may include two or more connectors, which may be located at an end or middle of a flex ion trap interconnect and configured to connect to an ion trap of a quantum computing system to transmit electrical signals to and from the ion trap.

### CROSS-REFERENCE TO RELATED APPLICATIONS

The present application claims the benefit of U.S. Provisional Patent Application Ser. No. 63/443,249, which was filed on Feb. 3, 2023, the entire contents of which is incorporated by reference herein for all purposes.

### TECHNICAL FIELD

Various embodiments relate to interconnects for an ion trap, such as an ion trap for use in a quantum charge-coupled device (QCCD)-based quantum computing system. An example embodiment relates more particularly to a flex ion trap interconnect.

### BACKGROUND

QCCD-based quantum computing systems use an atomic object confinement apparatus (e.g., an ion trap) that confines a plurality of atomic objects (e.g., ions) for use as qubits. The quantum computing system manipulates the quantum states of the qubits to execute quantum computing algorithms and/or circuits. The atomic object confinement apparatus operates in a vacuum chamber, such as a cryogenic vacuum chamber. The vacuum chamber is subject to strict requirements. For example, the vacuum chamber may be required to operate with a pressure at or below of 10-12 Torr. As a further example, a cryogenic vacuum chamber may be required to operate below a temperature of 20 Kelvin. Introduction of additional matter (e.g., gasses) disturbs the vacuum chamber and may cause failure in the quantum computing system. Disturbances may include additional matter that cause a vacuum as required by operational criteria to fail to exist. The operational criteria of quantum computing systems place heightened requirements on the vacuum chamber and the components therein. These components include the electrical interconnects that electrically couple the quantum computing system components in the vacuum chamber to each other as well as to external connections (e.g., voltage sources, optical sources, and/or the like). Thus the interconnects for use in quantum computing systems are required to meet the specific operational criteria of the vacuum chamber, including but not limited to pressure and/or temperature requirements. Through applied effort, ingenuity, and innovation, the inventors have identified numerous areas of improvement and many deficiencies, challenges, and problems have been solved by developing solutions that are structured in accordance with the embodiments of the present disclosure, many examples of which are described in detail herein.

### BRIEF SUMMARY OF EXAMPLE EMBODIMENTS

Example embodiments provide systems, apparatuses, methods, and/or the like for ion trap interconnects. For example, various embodiments provide systems, apparatuses, methods, and/or the like for use in a quantum computer (e.g., QCCD-based quantum computer), including for use as flexible ion trap interconnects in a vacuum chamber.

In accordance with an example embodiment of the present disclosure, and according to an aspect of the present disclosure, a quantum computing system is provided. In some instances, the quantum computing systems comprises: a vacuum chamber; an ion trap, wherein the ion trap is inside the vacuum chamber; and a flex ion trap interconnect electrically coupled to at least a first side of the ion trap, wherein the flex ion trap interconnect is configured to electrically transmit one or more signals to or from the ion trap.

In some instances, the vacuum chamber is a cryogenic vacuum chamber.

In some instances, the flex ion trap interconnect is coated with a metallic coating.

In some instances, the metallic coating is configured to reduce outgassing from the flex ion trap interconnect at pressures below a pressure of 10-12 Torr.

In some instances, the flex ion trap interconnect comprises a plurality of conductors and one or more electrical components connected to one or more of the plurality of conductors.

In some instances, the flex ion trap interconnect comprises a plurality of layers, and wherein each layer is comprised of at least one conductor.

In some instances, the ion trap is comprised of sapphire.

In some instances, the flex ion trap interconnect is further electrically coupled to a connector on a first sidewall of the cryogenic vacuum chamber.

In some instances, the quantum computing system further comprises a package, wherein the ion trap is electrically connected to the package by one or more electrical connections including a first electrical connection.

In some instances, the first electrical connection of the package and the ion trap is via the flex ion trap interconnect, wherein the flex ion trap interconnect is electrically coupled to the ion trap with a first connector and to the package with a second connector.

In some instances, wherein the one or more electrical connections include a second electrical connection, wherein the second electrical connection of the ion trap to the package includes at least one TSV and associated bond bump.

In some instances, the flex ion trap interconnect is further electrically coupled to a sidewall with a third connector.

In some instances, the flex ion trap further comprises a first connector comprising a first plurality of electrical terminals at a first end; and a second connector comprising a second plurality of electrical terminals at a second end.

In some instances, the flex ion trap interconnect further comprises a third connector comprising a third plurality of electrical terminals located between the first connector and the second connector.

In accordance with another example embodiment of the present disclosure, a flex ion trap interconnect apparatus is provided. The flex ion trap interconnect apparatus comprising: a first connector comprised of a first plurality of electrical terminals; a second connector comprised of a second plurality of electrical terminals; a ribbon comprised of a plurality of conductors electrically coupling the first plurality of electrical terminals of the first connector to the second plurality of electrical terminals of the second connector; and wherein the flex ion trap interconnect is configured to operate below a pressure of 10-12 Torr without off gassing.

In some instances, the flex ion trap interconnect further comprises a metallic coating.

In some instances, the ribbon comprises one or more openings.

In some instances, the flex ion trap interconnect further comprises one or more electrical components connected to one or more of the plurality of conductors.

In some instances, the flex ion trap interconnect further comprises a plurality of layers, wherein each layer is comprised of at least one conductor.

In some instances, the flex ion trap interconnect apparatus further comprises a third connector located between the first connector and the second connector.

The foregoing brief summary is provided merely for purposes of summarizing some example embodiments illustrating some aspects of the present disclosure. Accordingly, it will be appreciated that the above-described embodiments are merely examples and should not be construed to narrow the scope of the present disclosure in any way. It will be appreciated that the scope of the present disclosure encompasses many potential embodiments in addition to those summarized herein, some of which will be described in further detail below.

### BRIEF DESCRIPTION OF THE SEVERAL VIEWS OF THE DRAWING(S)

Having thus described the present disclosure in general terms, reference will now be made to the accompanying drawings, which are not necessarily drawn to scale, and wherein:

FIG. 1 illustrates an example quantum computing system in accordance with one or more embodiments of the present disclosure.

FIG. 2 illustrates an example of an ion trap and a flex ion trap interconnect in accordance with one or more embodiments of the present disclosure.

FIG. 3A illustrates a first view of an ion trap in accordance with one or more embodiments of the present disclosure.

FIG. 3B illustrates a second view of an ion trap in accordance with one or more embodiments of the present disclosure.

FIG. 4A illustrates an example of a flex ion trap interconnect in accordance with one or more embodiments of the present disclosure.

FIG. 4B illustrates a further example of a flex ion trap interconnect in accordance with one or more embodiments of the present disclosure.

FIG. 5A illustrates a further example of a flex ion trap interconnect with multiple layers in accordance with one or more embodiments of the present disclosure.

FIG. 5B illustrates a further example of a flex ion trap interconnect with multiple layers in accordance with one or more embodiments of the present disclosure.

FIG. 5C illustrates a further example of a flex ion trap interconnect with multiple layers in accordance with one or more embodiments of the present disclosure.

### DETAILED DESCRIPTION OF SOME EXAMPLE EMBODIMENTS

The present disclosure now will be described more fully hereinafter with reference to the accompanying drawings, in which some, but not all embodiments of the present disclosure are shown. Indeed, the present disclosure may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally,” “substantially,” and “approximately” refer to within engineering and/or manufacturing tolerances and/or within user measurement capabilities, unless otherwise indicated. Like numbers refer to like elements throughout.

Example embodiments provide systems, apparatuses, methods, and/or the like for a flex ion trap interconnect. For example, various embodiments provide systems, apparatuses, methods, and/or the like for the design and use of a flex ion trap interconnect for use in a quantum computing system, including but not limited to a flex ion trap interconnect located in a vacuum chamber of a quantum computing system.

Electrical interconnects electrically couple components of a quantum computing system to allow for and to direct the flow of electrical signals. In various embodiments of the present disclosure, these electrical interconnects include one or more flex ion trap interconnects. The flex ion trap interconnects may be configured to be flexible and to operate in the environment of a vacuum chamber without disturbing the strict operational criteria required for the vacuum chamber to allow for operation of the quantum system.

Conventional electrical interconnects used in vacuum chambers have multiple deficiencies. The conventional electrical interconnect of quantum computing systems for connecting a first component to a second component is a wire bond. A wire bond is a single metallic (e.g., gold) wire that connects an electrical terminal of a first component to an electrical terminal of a second component. A wire bond, however, is limiting in many ways including but not limited to those described herein. For example, as quantum computing systems become increasingly complex the number of connections needed are increasing and occupy larger and larger amounts of space and/or require higher densities of wire bonds in an available space. However, wire bonds require space so that no two wire bonds touch, and such a space requirement is both at each terminal of the wire bond as well as along the length of the wire bond. If two wire bonds touch, this may, among other things, create a short. For example, usage of wire bonds may be limited due to the terminals of wire bonds being located near the edge(s) of ion traps. As the number of connections needed for quantum systems increases the amount of space located near the edge(s) does not increase proportionally. In an example, using wire bonds on an ion trap in a vacuum chamber may be limited to one or two rows of wire bond terminals near the edge of the ion trap. While this may scale linearly if an ion trap grew in length—and this assumes an ion trap may grow in length, this scaling fails to scale faster than the number of connections needed is growing and/or the length of a wire bond may grow. Thus the use of wire bonds are limiting with regard to physical space, particularly as the number of electrical terminals to connect increases. Further, as the number of wire bonds increase the density of wire bonds may increase and, thus, a separation available between the wire bonds decreases. Such a decrease may limit the number of wire bonds that may be made. Further, the wire of wire bond is flimsy and sags, particularly as a wire bond increases in length. Thus a wire bond may require one or more supports to prevent the wire bond from sagging onto other wire bonds, which may weigh down other wire bonds, create shorts, and/or cause one or more wire bonds to fail. The creation of shorts is because wire bonds that touch (e.g., when one sags onto another) may cause a short circuit between wire bonds or an incorrect transmission of signals between wire bonds. While some wire bonds may be encapsulated in epoxy to minimize the risk of a short circuit, this may increase the amount of space each wire bond occupy as well as create manufacturing difficulty in working with the epoxy of individual wire bonds, such as at terminations. Further, examples of wire bonds with epoxy may include epoxies that outgas at the operation criteria required of vacuum chambers. An increase in the number of wire bonds also adds complexity when making connections to each terminal due to the small size of terminals and the increased numbers of wires, which limits the amount space available for terminations due to clear space needed around an ion trap. Additionally, wire bond connections are limited as they do not allow for complicated routing, such as a first electrical terminal of a first component being routed to more than one electrical terminal without requiring additional electrical terminals or interconnects. Additional limitations may be described herein.

Ion traps using these wire bond interconnects are also limited in their structure. Ion trap configurations making electrical interconnects using wire bonds also include ion trap configurations that connect or more ion trap components directly to each other. For example, an ion trap may contain multiple layers of components, such as an ion trap may be electrically and physically connected to an interposer, which may be electrically and physically connected to an application specific integrated circuit (ASIC), which may be physically connected to a spacer, which may be physically connected to a pin grid array (PGA) or land grid array (LGA). The interposer may be electrically connected to the ion trap, and the interposer may route signals via the interposer's conductors from the ion trap to additional terminals on the interposer, which may be further routed off the interposer by wire bonds. The ASIC may be electrically connected to the interposer and/or the ion trap (e.g., with a wire bond), and the ASIC may include electrical components for the switching or multiplexing of electrical signals. These layered components of an ion trap are stacked in multiple layers, sometimes referred to as a stack, and the spacer of a blank layer of silicon providing height so that the spacing of the ion trap is in the correct location to receive light from one or more light sources (e.g., lasers). Electrical connections between components of this stack may be soldered together, and if one component of the ion trap fails then the entire stack may fail.

In some configurations, soldering between electrical components (e.g., an ion trap and an interposer) may be to connect with through-silicon vias (TSVs). A TSV may pass through an electrical component from a first side of the electrical component (e.g., a top side) to a second side of the electrical component (e.g., a bottom side) A TSV and a bond bump may be used as an electrical connection between electrical components. However, in various configurations the use of TSVs may not only be expensive it may also be difficult to manufacture. For example, use of a TSV and a bond bump may limit the ability to use high-density routing on an ion trap. As another example, use of a TSV and a bond bump may be limited in allowing for testing and/or verifying the electrical connection until the end of manufacturing, at which point they cannot be repaired or reworked. This may create a stack with an error that cannot be tested until the end of manufacturing. Thus, a failure in a connection may cause the entire to stack to fail.

Additionally, ion trap configurations stacking ion trap components may also have the layers of the stack acting as insulators that prevent the dispersion of heat generated by operation of the quantum computing system. Such insulation is due to the layered ion trap components limiting the removal and control of heat in the ion trap, which may cause the quantum computer to function with a lower efficiency or to fail to function. For example, in some configurations of a cryogenic vacuum chamber the stacked layers of ion trap components may sit on a cold head or a cold finger, which is a portion of the cryogenic vacuum chamber kept at a low temperature, such as approximately 20 Kelvin or lower. The stacked layers of ion trap components, due to their insulation and thermal resistance, make it difficult to dissipate heat generated in or on the ion trap. By removing or relocating the layers, which may be possible in example embodiments by utilizing flex ion trap interconnects, there may be an improvement in thermal efficiency. In various embodiments, electrical components may be moved to a flex ion trap interconnect, such as electrical components otherwise on an ASIC. In various embodiments, the routing of an interposer may be done with a flex ion trap interconnect. Embodiments of the present disclosure, by removing and/or relocating one or more ion trap components between the ion trap and the package, provides for fewer layers between the ion trap and the cold finger. In such embodiments, the removal and/or relocation of one or more ion trap components allows for a reduction in thermal resistance, which provides greater control of temperature at the ion trap.

As another example, in a stack containing an ASIC, the ASIC may be a CMOS circuit that generates a first amount of heat. If, the ASIC is layered directly underneath the ion trap then the heat generated in the ASIC will transfer to the ion trap and, thus, heat up the ion trap. This additional heat transferred to the ion trap may make it harder to cool the ion trap to meet a operational criteria of the quantum computing system. In contrast, in various exemplary embodiments of the present disclosure, a flex ion trap interconnect may allow for the relocation or elimination of the ASIC such that, if present, the ASIC may be in the vacuum chamber near the ion trap but not directly connected or in contact with the ion trap. In such embodiments, while an ASIC may generate heat, the transfer of any heat to the ion trap is mitigated as the ASIC is not directly connected to the ion trap. In various exemplary embodiments of a cryogenic vacuum chamber, due to the operation of the ion trap at low temperatures, such as at approximately 20 Kelvin, movement of a heat source, such as an ASIC, away from the ion trap improves efficiency in controlling the temperature of the ion trap. Moreover, relocation of an ASIC to a sidewall of a vacuum chamber may allow for one or more heat sinks to be built within a wall of a vacuum chamber to direct heat generated from the ASIC outside of the vacuum chamber. While the ASIC is an example used here, movement of other layers of the stack are contemplated herein to further control and improve the thermal management, including cooling, of the ion trap.

Flex ion trap interconnects may additionally allow for improvements during the manufacturing and assembly of ion traps. For example, as ion traps continue to grow in complexity there is an increase in the numbers of electrodes, which increases the number of interconnects between the ion trap and other components. In examples using wire bonds, a greater number of interconnects requires a greater numbers of wire bonds, which increases the complexity of manufacturing the quantum computing systems as each additional wire bond interconnect needs to be terminated. Moreover, due to the closer proximity of bonding pads where wire bonds are terminated, the manufacturing may be difficult due to limited area to terminate a wire bond without disturbing one or more other wire bonds. This may limit how many bond pads or how close bond pads may be so that wire bonds may be made without disturbing other wire bonds. Further, the added complexity in manufacturing leads to greater numbers of manufacturing failures or rework due to the increased number of potential failure points. Also systems that solder, such as with TSVs and bump bonds, the layered components of a stack together, such as the ion trap, interposer, ASIC, and PGA/LGA, may be associated with complexity in manufacturing. Failure in any one of these components or associated interconnects between them causes a failure in the stack, which can be difficult to address. Relocating one or more of the components in the stack, such as with flex ion trap interconnects, provides improvements in ease of manufacturing and a reduction in failures as a flex ion trap interconnect needs only to redo one connector (e.g., a connector at a first end of the flex ion trap interconnect).

The flex ion trap interconnect of the present disclosure described herein provides multiple improvements over other electrical interconnects, such as wire bonds and as TSVs and bump bonds. The flex ion trap interconnect allows for high density of electrical terminals on multiple sides of an ion trap, which increases the number of electrical terminals for routing signals to and/or from the ion trap. Indeed, the distance between bond pads when using a flex ion trap interconnect may be closer together than when using wire bonds. This is due to, among other things, the use the connectors (e.g., end connectors) of the flex ion trap interconnects, which are described herein. Additionally, the use of flex ion trap interconnects may allow for additional bond pads to scale in more than one direction, such as in more than just a length of an ion trap due to the location of bond pads not being limited to being near the edges of the ion trap. Also, the flex ion trap interconnect also allows for the relocation of components in the vacuum chamber to improve heat dispersion, which allows for maintaining the strict requirements of the vacuum chamber. Flex ion trap interconnects may also allow for improvements in manufacturing and testing compared to TSVs and bond bumps. For example, while TSVs and bond bumps may not allow for testing a stack until after it is manufactured, embodiments of the present disclosure allow for a flex ion trap interconnect used with electrical components that may be tested at various points during manufacturing. Further, use of the flex ion trap interconnects may allow for rework of a portion of the electrical components without discarding an entirely manufactured stack. These are a few examples, and additional improvements over interconnects are described here.

The flex ion trap interconnect in accordance with the present disclosure includes a flexible circuit that provides for a high density of bond pads at each of a plurality of connectors on the flex ion trap interconnect to be electrically coupled. For example, the flex ion trap interconnect may include a first connector at a first end and a second connector at the second end. Each connector may contain a matching grid of bond pads where each of the bond pads of the first connector is electrically coupled by an electrical trace to an associated bond pad of the second connector. Thus the flex ion trap interconnect allows for an ion trap to include a large number of interconnects to be made in an ordered manner that allows for quick connection, support of the interconnects. Additional improvements described further herein.

The flex ion trap interconnect may be attached to an ion trap using solder. In various embodiments, a flux-free solder bond may be used, such as plated or solder jet solder pads or the like.

The flex ion trap interconnect is configured to operate in the vacuum chamber. A vacuum chamber may be required to operate below a pressure of 10-12 Torr. At these requirements, many materials used for flex circuits (e.g., polyimides) outgas. Outgassing is the releasing of one or more gases into an environment. However, in a vacuum chamber such outgassing introduces atoms of the gas into the environment which easily increases the pressure beyond the required 10-12 Torr of the vacuum chamber. Such an increase in pressure results in a failure to maintain the required pressure for operation of the quantum computing system. Example embodiments of a flex ion trap interconnect may limit or eliminate outgassing at the high vacuums that the vacuum chamber operates at. In various embodiments, materials with very low outgassing at 10-12 Torr may be used. Additionally, or alternatively, in various embodiments the flex ion trap interconnect may include one or more coatings of metal on its exterior surface that are configured to reduce and/or block outgassing from the flex ion trap interconnect, which may otherwise enter the environment. In various embodiments, the metallic coating may be configured to coat the flex ion trap interconnect except for the connectors (e.g., 232A, 232B, 232C). In various embodiments, once the flex ion trap interconnect is connected to an ion trap, the flex ion trap interconnect and/or one or more portions of a stack and/or ion trap may be coated with metal, such as with a flash of gold metal. Additionally, or alternatively, such a metallic coating may, for example, minimize stray electric fields.

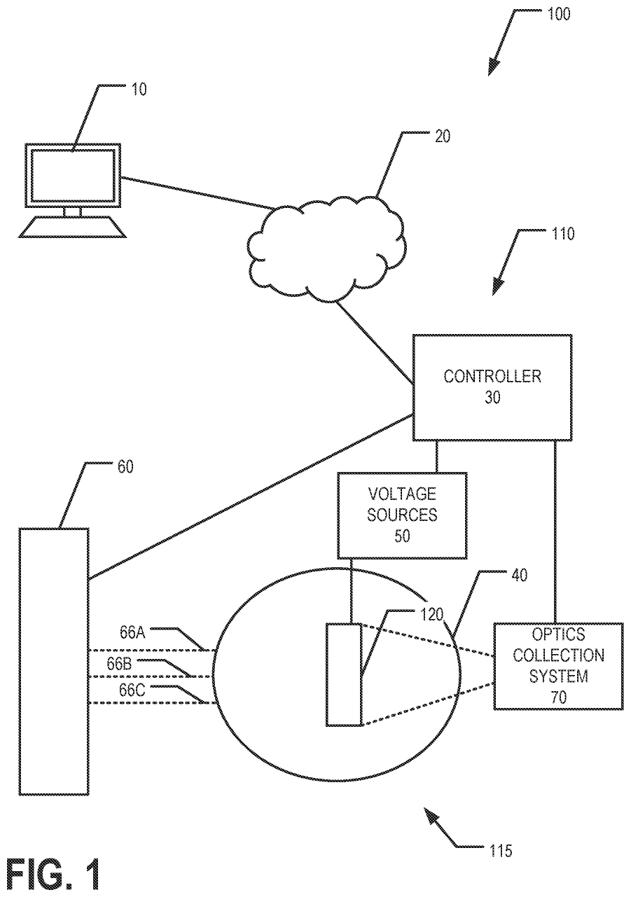

FIG. 1 illustrates an example quantum computing system in accordance with one or more embodiments of the present disclosure. The flex ion trap interconnect in accordance with the present disclosure may be used to efficiently electrical couple the components of a quantum computing system 100. In quantum computing system 100, the quantum processor comprises an atomic object confinement apparatus, such as an ion trap 120 or the like, which has a plurality of atomic objects (e.g., ions, atoms, and/or the like) confined therein.

In various embodiments, the quantum computing system 100 comprises a computing entity 10 and a quantum computer 110. The quantum computer 110 may comprise a quantum system controller 30 and a quantum processor. The quantum system controller 30 may be configured, programmed, and/or the like to control the quantum processor. The quantum processor may comprise a plurality of qubits (e.g., data qubits that may be organized into logical qubits, ancilla qubits, and/or the like). In various embodiments, the quantum computer 110 includes or communicates with databases (not illustrated). For example, the databases may be stored by one or more computing entities 10 that are in communication with the controller 30 via one or more wired and/or wireless networks 20 and/or stored by memory local to the controller 30.

The quantum processor comprises means for controlling the evolution of quantum states of the qubits. In various embodiments, the quantum processor comprises a vacuum chamber 40 and/or cryostat enclosing an ion trap 120, one or more manipulation sources 60, one or more voltage sources 50, and/or one or more optics collection systems 70. In various embodiments, the vacuum chamber 40 may be a cryogenic vacuum chamber and/or cryostat may be a temperature and/or pressure-controlled chamber. In various embodiments a vacuum chamber 40 that is not required to be a cryogenic vacuum chamber may be temperature and/or pressure-controlled for strict operational requirements but not at cryogenic temperatures.

In an example embodiment, the manipulation signals generated by the manipulation sources 60 are provided to the interior of the vacuum chamber 40 via optical paths (e.g., 66A, 66B, 66C). In an example embodiment, the one or more manipulation sources 60 may comprise one or more lasers (e.g., optical lasers, microwave sources, and/or the like). In various embodiments, the one or more manipulation sources 60 are configured to manipulate and/or cause a controlled quantum state evolution of one or more atomic objects within the ion trap 120. In various embodiments, the atomic objects within the atomic confinement apparatus (e.g., ions trapped within an ion trap) act as the data qubits and/or ancilla qubits of the quantum processor of the quantum computer 110. In an example embodiment, wherein the one or more manipulation sources 60 comprise one or more lasers, the lasers may provide one or more laser beams to atomic objects trapped within a confinement apparatus of an ion trap 120 within a vacuum chamber 40. The manipulation sources 60 may generate and/or provide laser beams configured to ionize atomic objects, initialize atomic objects within the defined two state qubit space of the quantum processor, perform gates one or more qubits of the quantum processor, read a quantum state of one or more qubits of the quantum processor, and/or the like.

In various embodiments, the quantum computer 110 comprises an optics collection system 70 configured to collect and/or detect photons generated by qubits (e.g., during reading procedures). The optics collection system 70 may comprise one or more optical elements (e.g., lenses, mirrors, waveguides, fiber optics cables, and/or the like) and one or more photodetectors. In various embodiments, the photodetectors may be photodiodes, photomultipliers, charge-coupled device (CCD) sensors, complementary metal oxide semiconductor (CMOS) sensors, Micro-Electro-Mechanical Systems (MEMS) sensors, and/or other photodetectors that are sensitive to light at an expected fluorescence wavelength of the qubits of the quantum computer 110. In various embodiments, the detectors may be in electronic communication with the quantum system controller 30.

In various embodiments, the quantum computer 110 comprises one or more voltage sources 50. For example, the voltage sources 50 may comprise a plurality of voltage drivers and/or voltage sources and/or at least one RF driver and/or voltage source. The voltage sources 50 may be electrically coupled to the corresponding potential generating elements (e.g., electrodes) of a confinement apparatus, such as ion trap 120. Varying the electrical potential(s) may move the ions between locations or states. In various embodiments, how to vary the electrical potential(s) may be defined by waveforms that specify one or more voltages to apply over a period of time. In various embodiments, the one or more voltage source 50 may be coupled to electrodes via circuitry, such as described herein. In various embodiments, the circuitry coupling the voltage sources 50 the electrodes may be located outside, inside, or both inside and outside the vacuum chamber 40 and/or cryostat. The circuitry coupling the voltage sources 50 to the electrodes located in the vacuum chamber 40 may utilize one or more the flex ion trap interconnects as described herein.

In various embodiments the circuitry coupling the voltage sources 50 to the electrodes, including flex ion trap interconnects, will be capable of and/or configured to operate at the pressures and/or temperature for their location, such as those in the vacuum chamber 40. For example, various embodiments of a vacuum chamber may operate at pressures below 10-12 or 10-13 Torr. As another example, various embodiments of a cryogenic vacuum chamber and/or cryostat may have pressures below 10-12 or 10-13 Torr and temperatures below 4 Kelvin.

In various embodiments, a computing entity 10 is configured to allow a user to provide input to the quantum computer 110 (e.g., via a user interface of the computing entity 10) and receive, view, and/or the like output from the quantum computer 110. The computing entity 10 may be in communication with the quantum system controller 30 of the quantum computer 110 via one or more wired or wireless networks 20 and/or via direct wired and/or wireless communications. In an example embodiment, the computing entity 10 may translate, configure, format, and/or the like information/data, quantum computing algorithms and/or circuits, and/or the like into a computing language, executable instructions, command sets, and/or the like that the quantum system controller 30 can understand and/or implement. For example, the controller 30 is configured to generate machine code level commands configured to, when executed by the appropriate components of the quantum computer 110, cause the performance of a quantum circuit by the quantum computer 110. In various embodiments, the performance of a quantum circuit may include providing and/or controlling voltages transmitted to and/or received from an ion trap 120 located in a vacuum chamber 40 via one or more flex ion trap interconnects.

In various embodiments, the quantum system controller 30 is configured to control the voltage sources 50, the pressure and/or temperature within the vacuum chamber 40, manipulation sources 60, and/or other systems controlling various environmental conditions (e.g., temperature, pressure, and/or the like) within the vacuum chamber 40 and/or configured to manipulate and/or cause a controlled evolution of quantum states of one or more atomic objects within the confinement apparatus. For example, the quantum system controller 30 may cause a controlled evolution of quantum states of one or more atomic objects within the ion trap 120 to execute a quantum circuit and/or algorithm. Additionally, the quantum system controller 30 may be configured to communicate and/or receive input data from the optics collection system 70 and corresponding to the reading of the quantum state of qubits of the quantum computer 110. In various embodiments, the atomic objects confined within a confinement apparatus, such as an ion trap 120, are used as qubits of the quantum computer 110.

In various embodiments, a quantum computer 110 comprises a quantum system controller 30 and a quantum processor. The quantum system controller 30 is configured to control various components of a quantum processor.

In various embodiments, the quantum system controller 30 is in communication with an optics collection system 70 such that the quantum system controller 30 is configured to receive input data captured and/or generated by the optics collection system 70. In various embodiments, the quantum system controller 30 is further configured to control the temperature and/or pressure within the vacuum chamber 40, cooling system, and/or other systems controlling the environmental conditions (e.g., temperature, humidity, pressure, and/or the like) within the vacuum chamber 40.

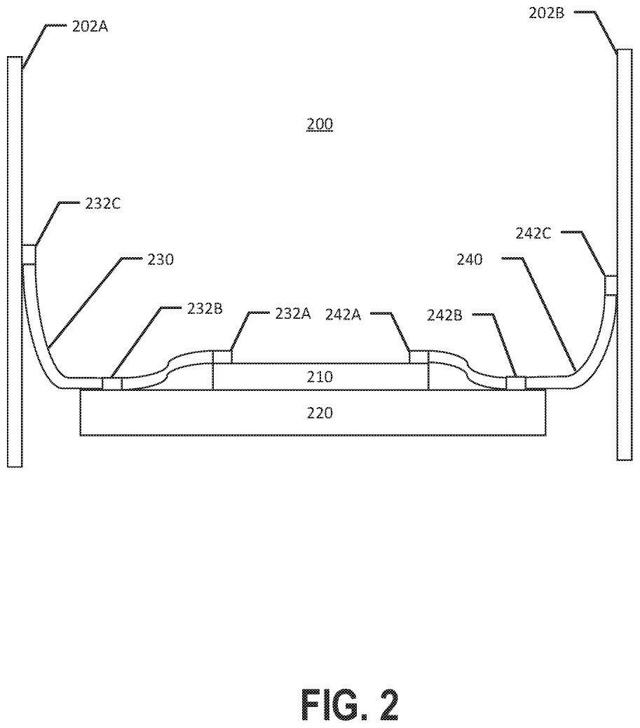

FIG. 2 illustrates an example of an ion trap and a flex ion trap interconnect in accordance with one or more embodiments of the present disclosure. FIG. 2 illustrates a cross section of a portion of an embodiment of vacuum chamber 200 having a first wall 202A and a second wall 202B, the other walls of the vacuum chamber 200 are not illustrated. Each of the first wall 202A and the second wall 202B are examples of sidewalls of the vacuum chamber 200. The vacuum chamber 200 contains an ion trap 210, a package 220, a first flex ion trap interconnect 230, and a second flex ion trap interconnect 240.

The first flex ion trap interconnect 230 and the second flex ion trap interconnect 240 may each include one or more connectors (e.g., 232A, 232B, 232C, 242A, 242B, 242C) that may be used to connect and/or disconnect these flex ion trap interconnects 232, 242 from one or more other components in the vacuum chamber 200. In various embodiments, such connectors allow for easy attachment, removal, and replacement of interconnects between components, which improves manufacturing, troubleshooting, and repair operations.

The first flex ion trap interconnect 230 includes three connectors: 232A, 232B, and 232C. Connector 232A is located at a first end of the first flex ion trap interconnect 230, connector 232B is located in the middle of the first flex ion trap interconnect 230, and connector 232C is located at a second end of the first flex ion trap interconnect 230. As illustrated in FIG. 2, connector 232A is connected to the top of a first side of the ion trap 210, connector 232B is connected to the package 220, and connector 232C is connected to the first wall 202A of the vacuum chamber 202A. The connection of a connector (e.g., 232C, 242C) to a wall may be to a connector on the side. In various embodiment, the connector on the sidewall may be a circuit board in and/or on the wall (not illustrated). For example, a circuit board maybe be mounted to a sidewall. Alternatively, a circuit board may be integrated into the sidewall. In various embodiments, the circuit board may create a connection not only for the flex ion trap interconnect (e.g., 232C, 242C) but it may also allow for a connection to an exterior connector outside of the vacuum chamber 40. In such embodiments the circuit board may allow for an electrical signal to pass through the sidewall to an external connector. Additionally, in various embodiments, a wall may be referred to as a sidewall, and the first wall 202A may be referred to as a first sidewall 202A of the vacuum chamber 200.

The second flex ion trap interconnect 240 includes three connectors: 242A, 242B, and 242C. Connector 242A is located at a first end of the second flex ion trap interconnect 240, connector 242B is located in the middle of the second flex ion trap interconnect 240, and connector 242C is located at a second end of the second flex ion trap interconnect 240. As illustrated in FIG. 2, connector 242A is connected to the top of a second side of the ion trap 210, connector 242B is connected to the package 220, and connector 242C is connected to the second wall 202B of the vacuum chamber 202A.

The first flex ion trap interconnect 230 and the second flex ion trap interconnect 240 connect to the ion trap 210 with connectors 232A, 242B that may be configured to be connected to the ion trap 210, such as with the bonding of one or more bond pads, which are described herein.

The first flex ion trap interconnect 230 and the second flex ion trap interconnect 240 connect to the package 220 with connectors 232B, 242B that may be configured to be connected to the package 220, such as with bonding to one or more bond pads and/or pins. The package 220 may include a pin grid array (PGA) and/or a land grid array (LGA), and the connectors may be configured to either receive pins from a PGA or provide pins to an LGA. The package 220 may also include one or more connectors (not depicted) that are configured to mate with the connectors 232B, 242B of the flex ion trap interconnects 230, 240.

In various embodiments, the use of flex ion trap interconnects 230, 240 allows for the removal or relocation of various components in the vacuum chamber 200. As illustrated in FIG. 2, the ion trap 210 may be directly connected to the package 220 and there are not one or more layers of other components, including, but not limited to, an interposer to route signals to and from the ion trap. Embodiments removing such additional layers may remove parasitic losses from routing signals through such additional layers, which may each then be connected with wire bonds and/or solder bonds. Each time a signal is transferred from one interconnection to another there are parasitic loses and, thus, the removal of the additional interconnects removes parasitic losses each interconnect introduces.

As illustrated in FIG. 2, a flex ion trap interconnect (e.g., 230) may route a signal to and/or from the ion trap 210 to either the package 220 and/or a first wall of the vacuum chamber 202A. The routing to the edge of the vacuum chamber 200 provides for the electrical signal be transferred out of the vacuum chamber 200, such as to a controller 30. In various embodiments, one or more components that may have been a layer of a stack (e.g., an ASIC) may be relocated to a wall of a vacuum chamber 40, such as the first wall 202A or the second wall 202B. One or more flex ion trap interconnects (e.g., 230, 240) may connect to these relocated components. In various embodiments, the ion trap 210 may include one or more TSVs and/or bonding pads on its bottom side, which may be connected to the package 220. In various embodiments, there may be a spacer (not illustrated) between the ion trap 120 and a package 220.

In various embodiments, ion traps (e.g., 210) may be made on, fabricated on, and/or include substrate(s) of different materials, such as silicon, sapphire, or the like. Silicon is a commonly used ion trap substrate material. Alternatively, sapphire may be used for the substrate of the ion trap (e.g., 210), which may offer multiple improvements over silicon. Such improvements may include but are not limited to sapphire having a higher thermal conductivity than silicon, which draws heat away from the surface of the ion trap. Additionally, sapphire is transparent and light may be transmitted to one or more locations in the ion trap 210 from one or more sides of the ion trap 210, including from the bottom or sides on the ends. Such transmission offer an improvement of allowing for additional areas from which to transmit light and routings of light. Further, sapphire has a lower conductivity than silicon, which may improve dissipation of RF signals.

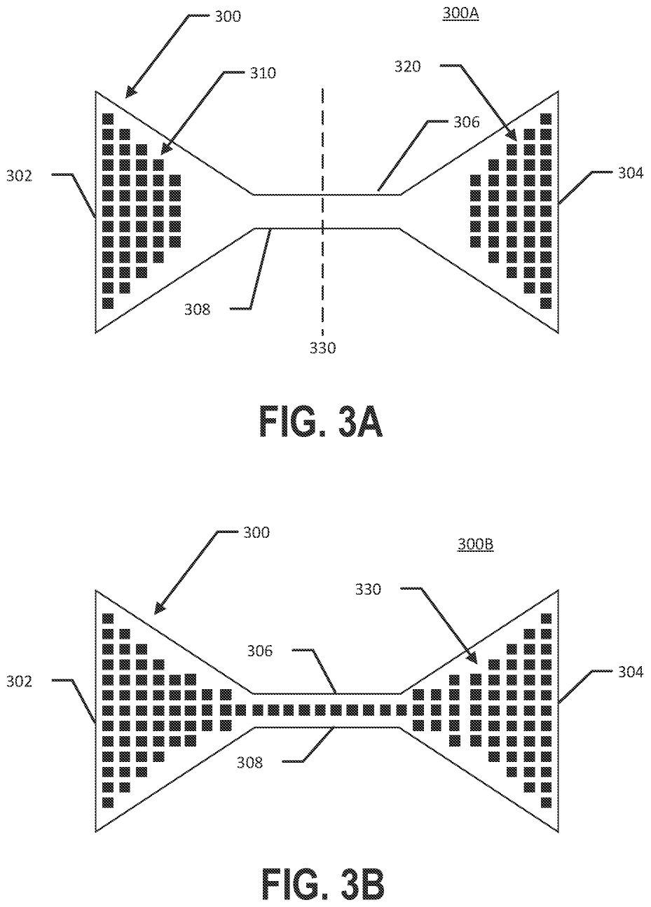

FIG. 3A illustrates a first view of an ion trap in accordance with one or more embodiments of the present disclosure. FIG. 3A is a top down view of an ion trap 300. Thus the top side 300A of the ion trap 300 is illustrated in FIG. 3A. In various embodiments, the ion trap 300 may, as illustrated, generally have a bow-tie shape with a top side 300A, a first side 302, a second side 304, a third side 306, and a fourth side 308. The top side 300A of the ion trap 300 includes a first plurality of bond pads 310 associated with the first side 302 of the ion trap 300 and a second plurality of bond pads 320 associated with the second side 304 of the ion trap 300. The illustration of the number of bond pads 310, 320 is not to scale and more or less bond pads are contemplated. Additionally, the number of rows of bond pads may be increased or decreased. However, the third side 306 and the fourth side 308 of the top side 300A are not associated with any bond pads as these sides of the ion trap 300 are where laser beams are received to manipulate ions.

The ion trap 300 may be shaped based on allowing for optical access of incident laser beams to be provided to the ion trap 300. In various embodiments, this may result in the generally bow-tie shape of the ion trap 300 illustrated in FIG. 3. This shape, due to the optical access requirements, limits the location bond pads 310, 315 to be located on a first end and second end. In various embodiments, the ion trap 300 may have a different configuration (e.g., it may not have a bow-tie shape). In these various embodiments, the location of the bond pads 310, 320 on the top of the ion trap 300 may be limited to the sides of the top of the ion trap 300 as the center of the ion trap 300 may be where light is directed. In various alternative embodiments (not illustrated), additional sides may each include a plurality of bonds pads.

In FIG. 3A, electrical signals may be transmitted to and/or from the ion trap 300 on the ends with bond pads while optical laser beams are transmitted into the ion trap from the narrowed sides. These narrowed sides for optical access allow laser beams to be focused to one or more points on the ion trap 300. For example, laser beams may be projected at the ion trap 300 directly at the ion trap (e.g., along axis 330) or at an angle (e.g., at a 45 degree angle from axis 330). Such a configuration allows for a cone shape expanding from the sides 306, 308 of the ion trap 300 for which a laser beam may be projected into the ion trap 300 due to the shape of the ion trap 300. The optical access is provided by keeping the shape of the ion trap 300 open on these sides to not impede one or more laser beams. Optical access requires that there be nothing (e.g., wires of wire bonds) impeding a laser beam and, similarly, that there be no bond pads. This limits the area of the ion trap 300 that may be utilized for bond pads to transmit electrical signals to and/or from the ion trap 300. Additionally, portions of the top side 300A of the ion trap 120 may not be available for bond pads due to these portions being the location where ions are present.

In various embodiments, the use of one or more flex ion trap interconnects allow, for example, for reduction of wires in the space above and/or near areas kept free of optical impedances to allow for optical access. The flex ion trap interconnects may allow for connection to the ion trap 300 and transmission of a signal without impeding in the area above and around the ion trap 300 where laser beams may be directed. In contrast, a wire bond requires space above and around the bond pad to expand away from the ion trap 300.

FIG. 3B illustrates a second view of an ion trap 300 in accordance with one or more embodiments of the present disclosure. FIG. 3B is a bottom up view of an ion trap 300. Thus the bottom side 300B of the ion trap 300 is illustrated in FIG. 3B. Thus the top side 300A of an embodiment of ion trap 300 is illustrated in FIG. 3A and the bottom side 300B is illustrated in FIG. 3B. As is readily seen in the figures, the ion trap 300 has sides 302, 304, 306, and 308.

In various embodiments, the entirety of the underside of ion trap 300 may be used for bond pads and transmitting signals to and/or from the ion trap 300. In various embodiments, a single flex ion trap interconnect may be connected to the bond pads 330 on the bottom side 300B of ion trap 300. In various embodiments, the bottom side 300B may be used in conjunction with flex ion trap interconnects for connecting to other components and/or TSVs. The TSVs may be located in a layer beneath the ion trap 300, such as in a spacer used to position the ion trap 300. In various embodiments, the ion trap 300 may include a TSV that goes through the ion trap to connect a bond pad at the top of the ion trap 300 with a bond pad at the bottom of the ion trap 300.

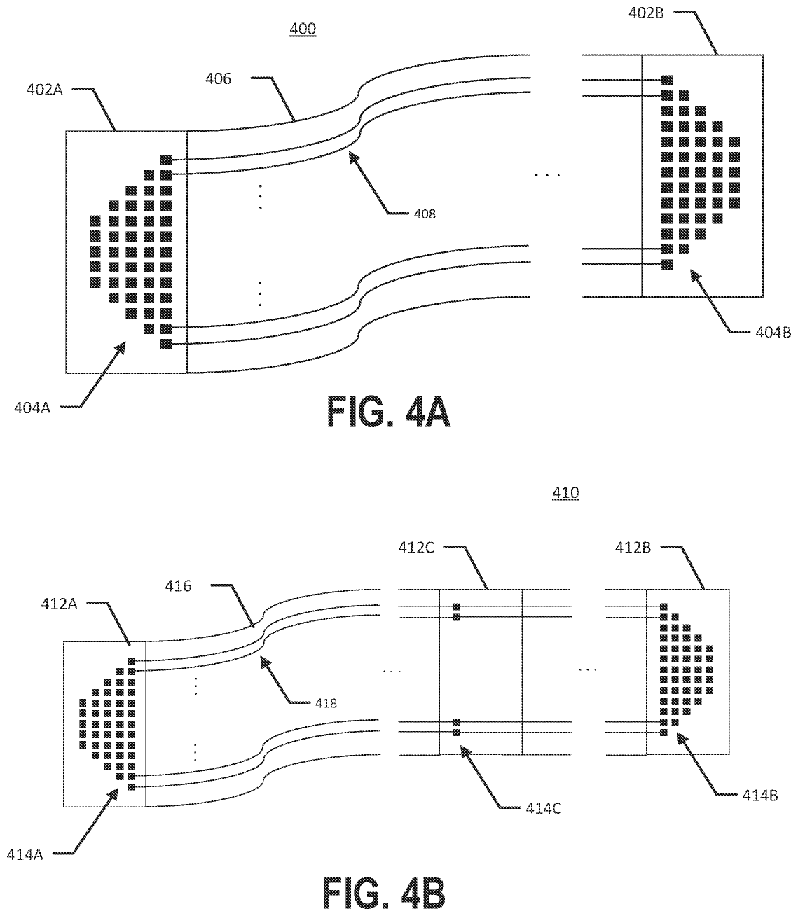

FIG. 4A illustrates an example of a flex ion trap interconnect 400 in accordance with one or more embodiments of the present disclosure. In various embodiments, the flex ion trap interconnect 400 includes a first end connector 402A at a first end and a second end connector 402B at a second end connected by a flexible ribbon 406. The first end connector 402A may include one or more bond pads 404A, and the second end connector 402B may include one or more bond pads 404B. Each of the bond pads 404A may be connected to one or more of the bond pads 404B by one or more flexible conductors 408. Alternatively, or additionally, each of the bond pads 404B may be connected to one or more of the bond pads 404A by one or more flexible conductors 408. Each of the one or more flexible conductors 408 in the flexible ribbon 406 in flex ion trap interconnect 400 may be separated by one or more dielectric materials.

FIG. 4B illustrates a further example of a flex ion trap interconnect 410 in accordance with one or more embodiments of the present disclosure. In various embodiments, the flex ion trap interconnect 410 includes a first end connector 412A and a second end connector 412B and a one or more middle connectors (e.g., 412C) located between the first end connector 412A and the second end connector 412B of the flex ion trap interconnect 410, and each of the first send connector 412A, second end connector 412B, and one or more middle connectors 412C may be connected by a flexible ribbon 416. The first end connector 412A may include one or more bond pads 414A, the second end connector 412B may include one or more bond pads 414B, and each middle connector (e.g., 412C) may include one or more bond pads 414C. Each of the bond pads 414A may be connected to one or more of the bond pads 414B and one or more bond pads 414C by one or more flexible conductors 418. Alternatively, or additionally, each of the bond pads 414B may be connected to one or more of the bond pads 414A and one or more bond pads 404C by one or more flexible conductors 418. Each of the one or more flexible conductors 418 in the flexible ribbon 416 in flex ion trap interconnect 410 may be separated by one or more dielectric materials.

In various embodiments, there may be two middle connectors 412C. In various embodiments there may be more than two middle connectors 412C. Each of the middle connectors 412C may include one or more bond pads 414C.

The first end connector (e.g., 412A), second end connector (e.g., 412B), and one or more middle connectors (e.g., 412C) utilize bond pads that may be connected to the bond pads of ion trap (e.g., 310, 320 of ion trap 300). Due to the soldered connection between the respective bond pads, the flex ion trap interconnects occupy much less space above an ion trap 300 (or below and ion trap 300 if connected to a bottom side) and, thus, do not interfere with the transmission of laser beams or impede on optical access for laser beams. In various embodiments this may increase the angle(s) at which a laser beam may be transmitted to the ion trap 300.

In various embodiments, the bond pads (e.g., 412A, 412B, 412C) may form a pattern on the connectors. The pattern may correspond to the one or more patterns of bond pads of an ion trap (e.g., 310, 320). The connection of the bonds pads (e.g., 412A) of a flex ion trap interconnect (e.g., 410) to the bond pads (e.g., 310) of an ion trap (e.g., 300) may be made between the bond pads with solder connections or the like.

In various embodiments, a flex ion trap interconnect may include two or more layers, such as with two or more layers in the ribbon 406. Alternatively, or additionally, the two or more layers of ribbon 406 may be separated to allow for additional ends (e.g., a third end) of the flex ion interconnect or to all for routing of the flex ion trap interconnect, such as when one of the layers includes a middle connector (e.g., 412C).

The bond pads of an end connector (e.g., 412A) may be routed through one or more of the layers to connect with bonds pads of another connector (e.g., 412B, 412C). In various embodiments, the routing may allow for redundant connections between a first end connector 412A and a second end connector 412B in order to ensure an electrical connection. Additionally, the use of multiple layers, each with its own conductor, connecting a bond pad at a first end connector 412A to a second end connector 412B may change an impedance between the two bond pads.

In various embodiments, flex ion trap interconnects (e.g., 230, 240, 400, 410) with more than one layer may include vias between layers that connect a conductor of a first layer with a conductor of a second layer.

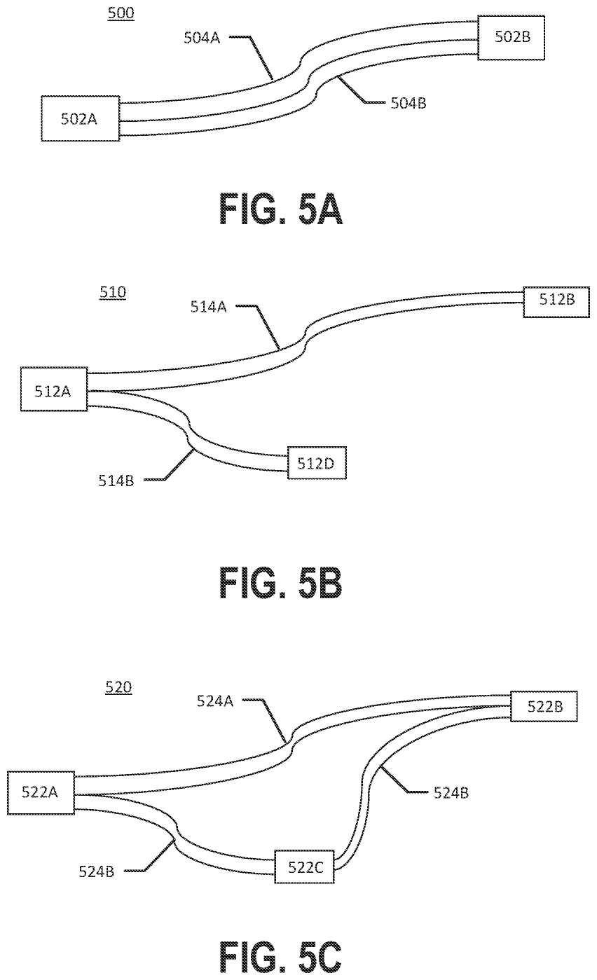

FIG. 5A illustrates an example of a flex ion trap interconnect 500 with multiple layers in accordance with one or more embodiments of the present disclosure. The flex ion trap interconnect 500 may include a first end connector 502A and a second end connector 502B. The first end connector 502A and the second end connector 502B are connected by a first layer 504A and a second layer 504B. Each of the first layer 504A and second layer 504B may be comprised of one or more ribbons including one or more conductors, and each of these ribbons may include one or more layers. The first layer 504A and the second layer 504B may be attached to each other. Alternatively, the first layer 504A and second layer 504B may not be attached or may not be attached for portions of the flex ion trap interconnect 500 such that the first layer 504A and the second layer 504B may be separated.

FIG. 5B illustrates a further example of a flex ion trap interconnect 510 with multiple layers in accordance with one or more embodiments of the present disclosure. The flex ion trap interconnect 510 may include a first end connector 512A, a second end connector 512B, and a third end connector 512D. A first layer 514A of the flex ion trap interconnect 510 may connect the first end connector 512A with the second end connector 512B, and a second layer 514B may connect the first end connector 512A with the second end connector 512D. Each of the first layer 514A and second layer 514B may be comprised of one or more ribbons including one or more conductors, and each of these ribbons may include one or more layers.

FIG. 5C illustrates a further example of a flex ion trap interconnect 520 with multiple layers in accordance with one or more embodiments of the present disclosure. The flex ion trap interconnect 520 may include a first end connector 522A, a second end connector 522B, and a middle connector 522C. A first layer 524A of the flex ion trap interconnect 520 may connect the first end connector 522A with the second end connector 522B, and a second layer 524B may connect the first end connector 522A with the second end connector 522B. The second layer 524B may also include a middle connector 522C between the first end connector 522A and the second end connector 522B. Each of the first layer 514A and second layer 514B may be comprised of one or more ribbons including one or more conductors, and each of these ribbons may include one or more layers.

In various embodiments, a layer (e.g., 504A) of a flex trap interconnect (e.g., 500) made be made of various materials, such as one or more variations of polyimide. The flex ion trap interconnect (e.g., 500), to be configured for operation in a vacuum chamber 40, may be coated with one or more metals, including the ribbon 406 of each layer (e.g., 504A) being coated with one or more metals. A metal coating may prevent molecules being released from the material of the flex ion trap interconnect (e.g., 504A), for example, a first polyimide, from outgassing and entering the vacuum chamber 40. Additionally, a metal coating may be electrically connected to a system ground to ground the flex ion trap interconnect (e.g., 504A). In various embodiments, the metal coating may coat the entirety of a ribbon, which may include one or more layers. Additionally, or alternatively, the metal coating may coat one or more of the connectors.

In various embodiments, a flex ion trap interconnect (e.g., 504A) may include one or more electrical components, such as passive electrical components (e.g., resistor, inductor, capacitor, etc.) or active electrical components (e.g., capacitor chips, ASICs, MMICs, etc.). The one or more electrical components may be attached and/or electrically coupled to one or more of the conductors 406 of a flex ion trap interconnect (e.g., 504A). The one or more electrical components may be removably connected, which may allow for the one or more electrical components to be removed, such as to replace the electrical components with another electrical component. Such embodiments may allow for the replacement of electrical components without requiring disassembling the ion trap stack or removing the flex ion trap interconnect.

In various embodiments, a flex ion trap interconnect (e.g., 520) may include one or more openings between the layers or one or more openings in a ribbon (e.g., 406). Such openings may allow for the flex ion trap interconnect be configured for placement around one or more other portions of the flex ion trap. Additionally, one or more openings may allow for the flex ion trap interconnect to be folded or routed in a configuration to fit different ion traps. Additionally, one or more openings may allow for middle connectors (e.g., 522C) to be connected to different portions of an ion trap (e.g., walls, components, etc.), including but not limited to connecting to, for example, one or more sides or portions of the ion trap and the walls. Additionally, one or more opening may be configured to allow for light to be transmitted to the ion trap.

In various embodiments, the flex ion trap interconnect may be include one or more layers of ribbon (e.g., 406) that may be used as mechanical support for other portions of ion trap interconnects, such as another flex ion trap interconnect or one or more wire bonds.

In various embodiments, a connector (e.g., end connector 412A, 412B, or middle connector 412C) may include one or more supports for supporting folds of a ribbon (e.g., 416), including but not limited to clamps, pins, braces, and/or the like.

In various embodiments, two or more flex ion trap interconnects may be connected in order to create a flex ion trap interconnect wiring harness. Such connections may be with one or more layers of each flex ion trap being mechanically connected, including but not limited to sharing one or more ribbons. A flex ion trap interconnect wiring harness may, for example, be used to create one or more configurations that support one or more other components or interconnects. In such embodiments, a wiring harness may reduce or eliminate one or more packaging stresses.

In various embodiments of the present disclosure, a stack may include an ion trap (e.g., 210), an interposer, a spacer, and/or a package (e.g., 220), and the stack may be connected to one or more flex ion trap interconnects (e.g., 230, 240). The flex ion trap interconnect (e.g., 230) may connect to the ion trap (e.g., 210), the interposer, and/or the spacer. The flex ion trap interconnect (e.g., 230) may also connect to one or more connectors on one or more sides of a vacuum chamber (e.g., 202A). Alternatively, in various embodiments, a stack may only include an ion trap (e.g., 210), which may be directly connected or bonded to a cold head or cold finger of a cryogenic vacuum chamber.

In various embodiments, a flex ion trap interconnect (e.g., 410) may include a first end connector (e.g., 412A) and a second end connector (e.g., 412B). Each of the first end connector (e.g., 412A) and the second end connector (e.g., 412B) may include a plurality of bond pads (e.g., 414A, 414B) in a configuration to match a plurality of bond pads on a ion trap for the first end (e.g., pattern at 310) and bond pads on a wall for the second end (e.g., pattern at 320). The bond pad configurations on the first end connector and the second end connector may be same or they may be different.

In various embodiments, an ion trap may be mechanically connected and/or coupled to a spacer to position the ion trap within a vacuum chamber 40. The ion trap and the spacer may include one or more TSVs, and the TSVs may be associated with respective bump pads that are soldered together to connect the ion trap and spacer. Alternatively, the spacer may be a solid material without TSVs, such as a substrate. The ion trap may be connected to one or more connectors on one or more walls of the vacuum chamber 40 via one or more flex ion trap interconnects (e.g., 230). In some embodiments, one flex ion trap interconnect (e.g., 230) may include one or more middle connectors (e.g., 232B) that may be connected to a wall. The ion trap 210 may be connected to the ion trap interconnect (e.g., 230) via the first end connector (e.g., 232A) on a first side. The flex ion trap interconnect (e.g., 230) may include a connection to a first wall at a middle connector (e.g., 232B) and a connection to a second wall (e.g., 202A) of the at the second end connector (e.g., 232C).

In various embodiments, a spacer may include TSVs (e.g., a DC TSV or an AC TSV), such as TSVs connecting a first side of the spacer and the second side of the spacer. The bottom of the ion trap may be electrically connector and/or coupled to a first side of the spacer (e.g., at the top) at one or more of the TSVs. At least one ion trap interconnect may include one or more connectors connected to the spacer at the TSVs on the second side of the space.

Many modifications and other embodiments of the present disclosure set forth herein will come to mind to one skilled in the art to which the disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A quantum computing system comprising:
a vacuum chamber;
an ion trap, wherein the ion trap is inside the vacuum chamber; and
a flex ion trap interconnect electrically coupled to at least a first side of the ion trap, wherein the flex ion trap interconnect is configured to electrically transmit one or more signals to or from the ion trap.

2. The quantum computing system of claim 1, wherein the vacuum chamber is a cryogenic vacuum chamber.

3. The quantum computing system of claim 1, wherein the flex ion trap interconnect is coated with a metallic coating.

4. The quantum computing system of claim 3, wherein the metallic coating is configured to reduce outgassing from the flex ion trap interconnect at pressures below a pressure of 10-12 Torr.

5. The quantum computing system of claim 1, wherein the flex ion trap interconnect comprises a plurality of conductors and one or more electrical components connected to one or more of the plurality of conductors.

6. The quantum computing system of claim 1, wherein the flex ion trap interconnect comprises a plurality of layers, and wherein each layer is comprised of at least one conductor.

7. The quantum computing system of claim 1, wherein the ion trap is comprised of sapphire.

8. The quantum computing system of claim 1, wherein the flex ion trap interconnect is further electrically coupled to a connector on a first sidewall of the cryogenic vacuum chamber.

9. The quantum computing system of claim 1 further comprising:
a package, wherein the ion trap is electrically connected to the package by one or more electrical connections including a first electrical connection.

10. The quantum computing system of claim 9, wherein the first electrical connection of the package and the ion trap is via the flex ion trap interconnect, wherein the flex ion trap interconnect is electrically coupled to the ion trap with a first connector and to the package with a second connector.

11. The quantum computing system of claim 10, wherein the one or more electrical connections include a second electrical connection, wherein the second electrical connection of the ion trap to the package includes at least one TSV and associated bond bump.

12. The quantum system of claim 10, wherein the flex ion trap interconnect is further electrically coupled to a sidewall with a third connector.

13. The quantum system of claim 1, wherein the flex ion trap interconnect further comprises:
a first connector comprising a first plurality of electrical terminals at a first end; and
a second connector comprising a second plurality of electrical terminals at a second end.

14. The quantum system of claim 13, wherein the flex ion trap interconnect further comprises:
a third connector comprising a third plurality of electrical terminals located between the first connector and the second connector.

15. A flex ion trap interconnect apparatus comprising:
a first connector comprised of a first plurality of electrical terminals;
a second connector comprised of a second plurality of electrical terminals;
a ribbon comprised of a plurality of conductors electrically coupling the first plurality of electrical terminals of the first connector to the second plurality of electrical terminals of the second connector; and
wherein the flex ion trap interconnect is configured to operate below a pressure of 10-12 Torr without off gassing.

16. The flex ion trap interconnect apparatus of claim 15 further comprising a metallic coating.

17. The flex ion trap interconnect apparatus of claim 15, wherein the ribbon comprises one or more openings.

18. The flex ion trap interconnect apparatus of claim 15 further comprising one or more electrical components connected to one or more of the plurality of conductors.

19. The flex ion trap interconnect apparatus of claim 15 further comprising a plurality of layers, wherein each layer is comprised of at least one conductor.

20. The flex ion trap interconnect apparatus of claim 15 further comprising a third connector located between the first connector and the second connector.
